(19) United States
(12) Patent Application Publication
(10) Pub. No.: US 2025/0299963 A1
(43) Pub. Date: Sep. 25, 2025

(54) PHOTOLITHOGRAPHIC MASKS AND DEVICES FABRICATED THEREFROM

(71) Applicant: TEXAS INSTRUMENTS INCORPORATED, Dallas, TX (US)

(72) Inventors: Jonas Hoehenberger, Kissing (DE); Ryan Savage, Richardson, TX (US); Steve Prins, Fairview, TX (US); Scott Jessen, Allen, TX (US)

(21) Appl. No.: 18/609,282

(22) Filed: Mar. 19, 2024

(51) Int. Cl. H01L 21/308; H01L 21/02; H01L 29/06; H01L 29/40

(52) U.S. Cl. CPC H01L 21/3086; H01L 21/02422; H10D 62/117; H10D 64/111

(57) ABSTRACT

Mask devices for photolithography used in semiconductor and other device fabrication are described. For example, a mask device includes a light-passing substrate and a patterned opaque layer disposed on the light-passing substrate. The patterned opaque layer includes a light-modulating region with elongate features consecutively disposed at increasing distances from one another.

### TECHNICAL FIELD

The present disclosure relates to the field of photolithography, and more particularly to photolithographic masks and devices fabricated using such photolithographic masks.

### BACKGROUND

Photolithography is a frequently used process in semiconductor and other device fabrications. While some photolithography techniques are maskless, where light is applied directly to a photosensitive material of a photoresist layer formed on a semiconductor or other layer of the device being fabricated, other photolithography techniques utilize a mask device (referred to, e.g., as a mask or reticle). In the latter case, light is shone onto a surface of the mask device positioned between the light source and the semiconductor device being fabricated. Based on a mask pattern formed on a surface of the mask device, light passes through the mask device to the photoresist layer in certain areas while being blocked in other areas.

A mask device can be a clear field mask or a dark field mask. In a clear field mask, the patterned features on a surface of the mask device block light while the other surface areas pass light. Conversely, in a dark field mask, the patterned features pass light, while the other surface areas block light. Still further, the underlying photoresist layer formed on the device being fabricated can be positive or negative. In a positive photoresist, portions of the photosensitive material are removed when exposed to light and developed. Conversely, in a negative photoresist, portions of the photosensitive material are removed when developed unless exposed to light.

A profile is thereby formed in the photoresist layer based on the mask pattern and then transferred to the underlying layer of the device being fabricated to form one or more structures therein.

### SUMMARY

The present disclosure describes mask patterns and mask devices for photolithography used in semiconductor and other device fabrication. This summary is not an extensive overview of the disclosure. Rather, a purpose of the summary is to present some examples of the present disclosure in a simplified form as a prelude to a more detailed description that is presented later.

In some examples, a mask device includes a light-passing substrate and a patterned opaque layer disposed on the light-passing substrate. The patterned opaque layer includes a light-modulating region with elongate features consecutively disposed at increasing distances from one another.

In some other examples, a method of fabricating a mask device includes forming an opaque layer on a light-passing substrate, and applying a mask pattern to the opaque layer to form a patterned opaque layer including a light-modulating region with elongate features consecutively disposed at increasing distances from one another.

In some additional examples, a semiconductor device includes a substrate and at least one layer disposed in relation to the substrate, where the at least one layer comprises a structure with at least one rounded portion having a non-segmented contour.

### BRIEF DESCRIPTION OF THE DRAWINGS

FIG. 1 is a block diagram of a mask device fabrication process with which one or more examples of the present disclosure may be implemented;

FIGS. 2A through 2C are top views of pixel-based mask patterns for fabricating mask devices;

FIGS. 3A and 3B are top views of elongate feature-based mask patterns for fabricating mask devices in accordance with examples of the present disclosure;

FIGS. 3C and 3D are schematic cross-sectional and three-dimensional views, respectively, of an elongate feature-based mask device in accordance with an example of the present disclosure;

FIG. 4 is a top view of an elongate feature-based mask pattern for fabricating mask devices in accordance with another example of the present disclosure;

FIG. 5A is a cross-sectional view of a semiconductor device formed in accordance with an example of the present disclosure;

FIG. 5B is a top view of an elongate feature-based mask device used to fabricate a portion of the semiconductor device of FIG. 5A;

FIG. 5C is a three-dimensional view of a sloped sidewall structure formed in the semiconductor device of FIG. 5A using the mask device of FIG. 5B;

FIG. 6A is a cross-sectional view of a semiconductor device formed in accordance with another example of the present disclosure;

FIG. 6B is a top view of an elongate feature-based mask device used to fabricate a portion of the semiconductor device of FIG. 6A;

FIG. 6C is a three-dimensional view of a sloped sidewall structure formed in the semiconductor device of FIG. 6A using the mask device of FIG. 6B;

FIG. 7 is a cross-sectional view of a semiconductor device formed in accordance with yet another example of the present disclosure; and

FIGS. 8A and 8B are flow diagrams of methodologies for fabricating mask devices from elongate feature-based mask patterns in accordance with examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

While examples are described herein for utilizing elongate feature-based mask devices to fabricate semiconductor devices (e.g., transistors, capacitors, or the like), such mask devices can be utilized in alternative fabrication examples such as, but not limited to, microelectromechanical systems (MEMS), nanostructures, or the like.

As mentioned, photolithographic mask devices are used to form one or more structures in a semiconductor device or other types of devices. While photolithographic techniques have been proposed to enable fabrication of structures with certain shapes, they have largely focused on two-dimensional (2D) shaping, e.g., mainly linear-based shapes defined in x and y dimensions on a plane where the structures have substantially perpendicular sidewalls in a z dimension orthogonal to the plane. However, one specific form of photolithography, referred to as grayscale photolithography, has been proposed to facilitate three-dimensional (3D) structure shaping, e.g., structures defined in x and y dimensions on a plane with non-perpendicular (e.g., sloped, tapered, contoured) sidewall profiles.

More particularly, grayscale mask-based lithography uses a mask device (e.g., sometimes referred to as a grayscale mask or grayscale reticle) to spatially modulate or modify the light intensity or dosage applied to a photoresist layer formed on an underlying layer of the device being fabricated. By way of example, the light applied to the grayscale mask device typically is ultra-violet (UV) light. Modulation of the light is enabled by a patterned opaque layer disposed on a light-passing substrate. The patterned opaque layer includes areas of opaque material (opaque areas of the patterned opaque layer) and areas without opaque material (open areas of the patterned opaque layer where a surface of the light-passing substrate is exposed). For example, the opaque areas can be composed of a metal material such as, but not limited to, chrome, chromium, and/or a metal oxide. The light-passing substrate can be composed of a light-passing material such as, but not limited to, quartz, fused silica, and/or glass. Thus, in one example, a grayscale mask device can be fabricated where chrome serves as the opaque material and glass serves as the light-passing material. Such a mask device is sometimes referred to as a chrome-on-glass (COG) mask. In general, such a mask can also be referred to as a binary mask given its functionality to block light in certain areas and pass light in other areas.

During the grayscale photolithographic process, the applied light is blocked or obstructed by opaque areas of the patterned opaque layer while passing through the open areas and then through the substrate. More particularly, grayscale mask devices rely on the concept of diffraction where light bends or spreads around the edges of the opaque areas while passing through the open areas of the patterned opaque layer.

Accordingly, the term “opaque,” as illustratively used herein, refers to a characteristic of a material to block applied light by reflection, absorption, and/or some other light-blocking functionality. The term “light-passing,” as illustratively used herein, refers to a characteristic of a material to enable all or most of the applied light to pass (e.g., transparent material) or some portion of the applied light to pass (e.g., translucent or semitransparent material).

In a clear field mask, the pattern features formed in the patterned opaque layer on a surface of the light-passing substrate are composed of opaque material and thus block light, while clear or open areas (lack of opaque material) expose the surface of the light-passing substrate and thus pass light. In contrast, in a dark field mask, the pattern features on the surface are clear or open areas (pass light) while the other areas on the surface are opaque material and thus block light. Depending on the structures being fabricated in the underlying device, either type of mask device (clear field or dark field) can be used with a positive photoresist material or a negative photoresist material.

The modulated light passing through the mask device, e.g., measured as an intensity-pass percentage, correspondingly modulates or modifies the amount of photosensitive material that is removed (positive photoresist) or remains (negative photoresist) in the photoresist layer to form a profile in the photoresist layer. Thus, in a positive photoresist example, the more light that passes through the mask device (e.g., higher intensity-pass percentage) onto the photoresist layer, the more photosensitive material of the photoresist layer is removed during development (e.g., decreasing the thickness of the photoresist layer from its original thickness). Thus, by modulating the applied light to change the exposure dose or intensity locally in the photoresist layer, profiles can be selectively formed in the photoresist layer, e.g., non-perpendicular photoresist sidewall profiles. The profiles can then be transferred to the underlying layer of the semiconductor device to fabricate various structures of the semiconductor device.

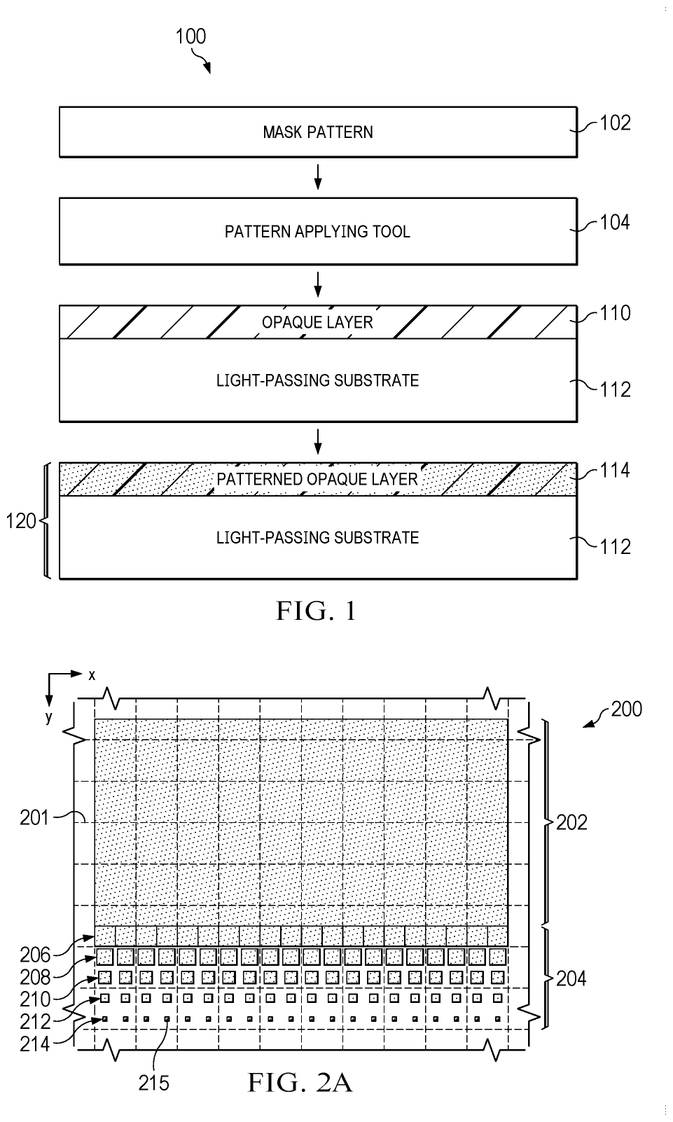

Referring now to FIG. 1, a mask device fabrication process 100 is generally shown. Initially, a mask pattern 102 is generated. In some examples, mask pattern 102 is generated using a computer-based software package such as a computer-aided design (CAD) system. The CAD system enables a designer, on a computer system with a graphical user interface, to create an image of a specific geometry of features on a layout grid that will result in a specific profile being formed in a photoresist layer. The specific profile in the photoresist layer then dictates the resulting shape (e.g., contour) of one or more corresponding structures in the underlying layer of the semiconductor device. One example of a layout grid on which a designer can lay out mask pattern features via the CAD system is a coordinate grid of equally-sized square cells. However, as will be further described, alternative layout grids can be used.

Once generated, mask pattern 102 is input to a pattern applying tool 104. For example, mask pattern 102 generated by the designer via the CAD system can be saved as a software data file that is readable by pattern applying tool 104. Pattern applying tool 104 is configured to read the mask pattern file and transfer the mask pattern 102 onto an opaque layer 110 disposed on a surface of a light-passing substrate 112 resulting in a patterned opaque layer 114, as shown in FIG. 1.

In some examples, pattern applying tool 104 is a laser-based pattern writing system. Preparation of the opaque layer 110 prior to the laser-based pattern writing process may be dependent on the particular system being used. However, in some examples, opaque layer 110 will have its own photoresist layer disposed thereon (not expressly shown) such that mask pattern 102 is applied to the photoresist layer. After development, mask pattern 102 is transferred to opaque layer 110 resulting in patterned opaque layer 114.

Accordingly, as shown in FIG. 1, a mask device 120 is fabricated including light-passing substrate 112 with patterned opaque layer 114 disposed thereon. Patterned opaque layer 114, as mentioned above, includes opaque areas that, during semiconductor device fabrication, reflect, absorb, or otherwise block the applied light while allowing light to pass through open areas (e.g., where no opaque material is disposed) and thus through the light-passing substrate 112.

The complexity of structures formed in a semiconductor device using a mask device (e.g., mask device 120) is directly related to the mask pattern (e.g., mask pattern 102) formed on the mask device. Accordingly, the mask pattern dictates the positioning of the features in the patterned opaque layer (e.g., patterned opaque layer 114) of the mask device and thus the profile formed in a photoresist layer. However, the fabrication of the mask device with its mask pattern design can present technical challenges to designers, as well as to the pattern applying tools that are utilized, depending on the desired profiles and structures. This is particularly the case when generating mask patterns that are intended to result in more complex structures in the semiconductor device, e.g., 3D structures based on the grayscale photolithography and the like.

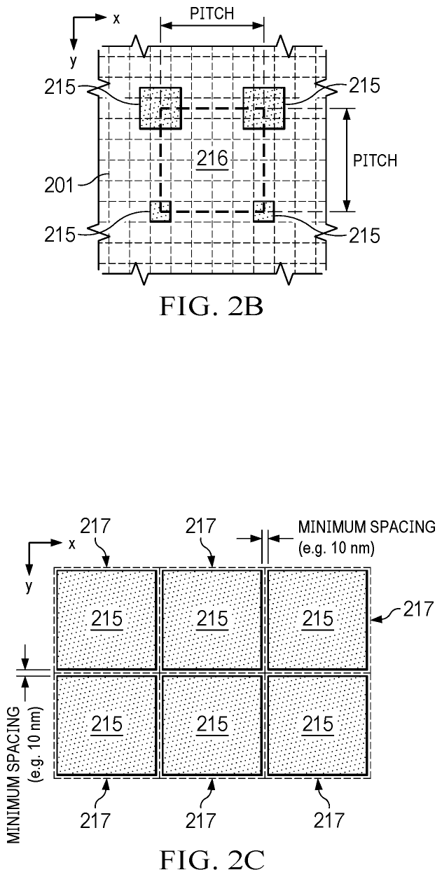

One feature geometry that has been utilized for mask patterns in grayscale photolithography is based on square features or pixels. In a pixel-based mask pattern, each individual pixel is intended to have equal, or relatively equal, length and width. FIG. 2A illustrates an example of a pixel-based mask pattern 200 generated on a 2D (x-dimension and y-dimension) coordinate grid of equally-sized square cells referenced as a layout grid 201 (e.g., dashed line grid as shown). Pixel-based mask pattern 200 includes a non-modulating region 202 and a modulating region 204 positioned on the layout grid 201. Non-modulating region 202 corresponds to a part of the mask device formed from pixel-based mask pattern 200 that does not cause modulation of the applied light. On the other hand, modulating region 204 corresponds to a part of the mask device formed from pixel-based mask pattern 200 that causes modulation of the applied light. It is assumed here, in this example, that the pixel features on the actual mask device will be opaque (e.g., a clear field mask implementation).

Modulating region 204 includes a plurality of pixel sets 206 through 214. Each of pixel sets 206 through 214 has multiple pixels 215 that are equally-sized within the particular pixel set. However, with respect to one direction of the y-dimension as shown, pixels 215 of each consecutive pixel set are smaller in area than the preceding pixel set. The rational for this design is that the light intensity passing through the mask device formed from the mask pattern, such as pixel-based mask pattern 200, is dependent upon the fill factor of a pitch area defined between pixels as described below in more detail.

FIG. 2B shows an example of pitch between adjacent pixels 215. While pitch can be measured from different perspectives, in the example shown here, the pitch is measured between centers of adjacent pixels 215. Moreover, a pitch area 216 may be defined therebetween such that four corners of the pitch area 216 correspond to the four centers of adjacent pixels 215. For instance, when the mask pattern is designed with pixels and a uniform pitch between pixels, then the intensity-pass percentage, as mentioned above, depends on the percentage of pitch area 216 that is filled by portions of adjacent pixels.

While pixel-based mask pattern 200 can result in certain structures being formed in a semiconductor device, there are technical drawbacks that prevent or detract from the formation of other, more complex, structures. For example, pixel-based mask pattern 200 is not able to adequately cause formation of structures that have one or more rounded corners or curves. More particularly, attempting to form structures with one or more rounded corners or curves using pixel-based mask pattern 200 results in a segmentation issue, e.g., the structure exhibits unwanted steps, angles, edges, waviness, and/or undulation (e.g., a segmented contour) in the one or more rounded corners, contours, or curves of the structure.

Another technical drawback of pixel-based mask pattern 200 is that only pixels which are a multiple of a minimum pixel area can be generated by many commercially-available laser-based pattern writing systems used to apply the mask pattern to the opaque layer of the mask device. Thus, as illustrated in FIG. 2A, assuming each pixel 215 in pixel set 214 is generated with a minimum pixel area, each pixel 215 in pixel set 212 is generated with an area that is, e.g., four times the minimum pixel area, each pixel 215 in pixel set 210 is generated with an area that is, e.g., nine times the minimum pixel area, and so on. This minimum pixel area limitation can also be seen in pixels 215 shown in FIG. 2B (e.g., the area of each of the two upper pixels in the figure is a multiple of the area of each of the two lower pixels).

Yet another technical drawback of pixel-based mask pattern 200 is the minimum spacing between pixels 215. For example, assume a portion of a modulating region in a mask pattern is intended to achieve a 10% intensity-pass percentage (e.g., 10% of the applied light passes through the mask device). FIG. 2C shows a pixel arrangement of pixels 215 on respective cells 217 of a layout grid designed to achieve an intensity-pass percentage of 10%. Note that, for case of explanation, FIG. 2C shows pixels 215 in the same pixel set and in consecutive pixel sets as having the same pixel area.

Assuming each cell 217 in FIG. 2C is 100 nanometers (nm)×100 nm in area, to achieve a 10% intensity pass, each pixel 215 has a fill factor of 95%, e.g., the pixel area is 95 nm×95 nm. As such, the minimum spacing in both the x and y dimensions between two pixels 215 has to be 10 nm due to a 5 nm border around each pixel 215 within each cell 217 dictated by the 95% fill factor. However, many commercial laser-based pattern writing systems have a problem with forming features on the mask device with such a minimum distance therebetween.

To address the above and other technical drawbacks associated with pixel-based mask pattern designs, as well as other mask pattern designs, the present disclosure describes a mask pattern design that is based on elongate features, which may be referred to as an elongate feature-based mask pattern as compared to the pixel-based mask pattern described above. By way of example only, the elongate feature design of the present disclosure advantageously eliminates the above-mentioned minimum pixel area limitation, alleviates the minimum spacing limitation, and addresses the contour segmentation issue, as will be described in further detail herein. The elongate feature design of the present disclosure may also overcome other technical drawbacks associated with pixel-based and other mask designs.

The term “elongate” illustratively used herein refers to a non-square feature that extends in one geometric direction more than in another geometric direction. By way of example only, an elongate feature can be characterized as having a geometry that has a length that is greater than its width. However, the term elongate can alternatively refer to a feature that has a width that is greater than its length, depending on how the relative geometry of the feature is defined in the mask design. Furthermore, an elongate feature according to the present disclosure can be relatively straight (linear) along its entire length or bent in one or more locations along its length. In examples shown in the figures, elongate features are bent having one or more rounded corners or squared corners along their lengths. Thus, based on its linear geometry and/or shape along its length relative to width, an elongate feature is distinguishable from a pixel feature which has the same (or relatively the same) length and width.

Note that the term “elongate feature” is illustratively referred to herein in the context of a mask pattern designed and generated as part of an image in two dimensions on a CAD system. However, the corresponding feature formed on a resulting patterned opaque layer (e.g., patterned opaque layer 114 in FIG. 1) of the mask device itself is also referred to as an elongate feature. In a clear field mask implementation, an elongate feature on the actual mask device is opaque and thus also has some thickness which is dependent on the material used to form the elongate feature. In a dark field mask implementation, elongate features are open areas (no opaque material) and the areas between or otherwise around elongate features are opaque and thus have some material thickness. Accordingly, while the term elongate feature is used herein with respect to both the mask pattern and the actual resulting mask device, its context will be clear from the given descriptions.

The length and width of an elongate feature on the mask pattern corresponds to the length and width of the resulting elongate feature on the mask device. Depending on the size of the mask device being fabricated, such correspondence can be one-to-one or scaled. In one-to-one correspondence, the lengths and widths of the elongate features of the mask pattern are identical or substantially identical to the lengths and widths of the resulting elongate features of the mask device. In scaled correspondence, the lengths and widths of the elongate features of the mask pattern are scaled proportionally (up or down) with respect to the lengths and widths of the elongate features of the mask device.

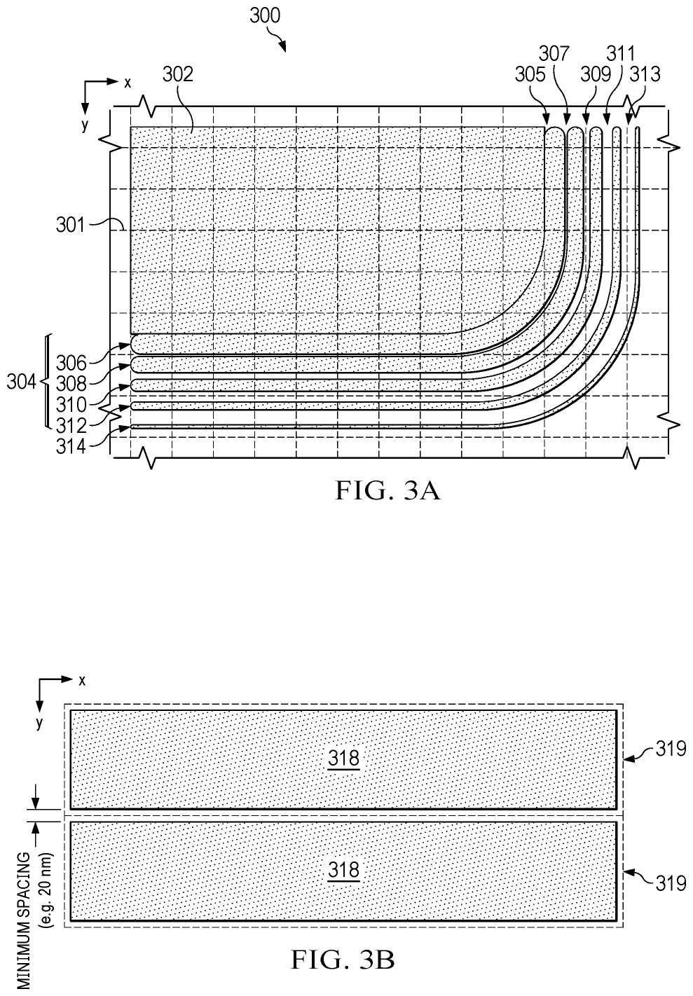

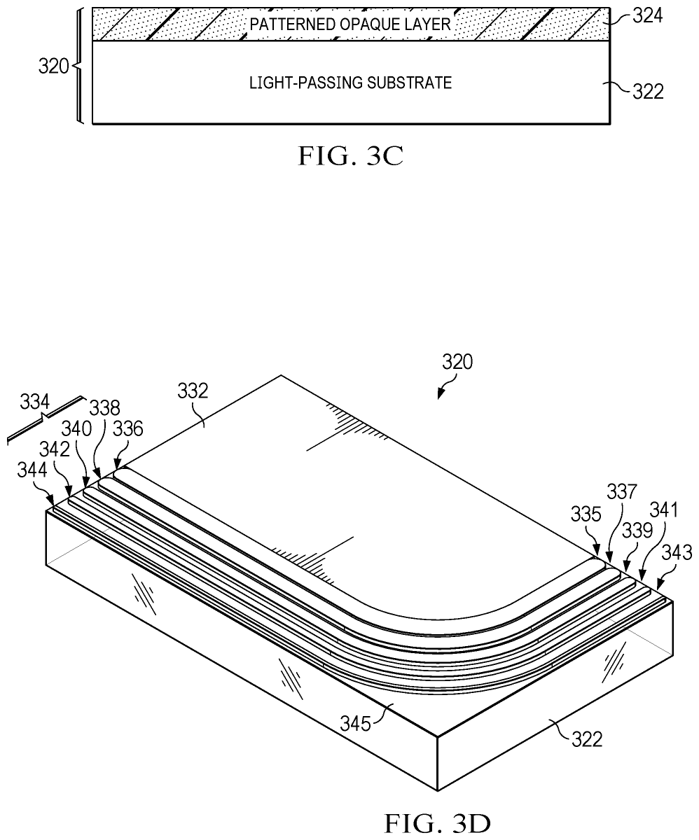

FIG. 3A illustrates an example of an elongate feature-based mask pattern 300 usable to fabricate a clear field mask implementation. While elongate feature-based mask pattern 300 is shown on a coordinate grid of equally-sized square cells referenced as a layout grid 301 (e.g., dashed line grid), elongate feature-based mask pattern 300 is not constrained by the square cell layout grid. Thus, alternative layout grids can be used such as ones that have other cell configurations, e.g., elongate cells as will be described below in the context of FIG. 3C.

As shown in FIG. 3A, elongate feature-based mask pattern 300 includes a non-modulating region 302 and a modulating region 304. Non-modulating region 302 corresponds to a part of the mask device formed from elongate feature-based mask pattern 300 that does not cause modulation of the applied light—e.g., the applied light is blocked in its entirety. Modulating region 304 corresponds to a part of the mask device formed from elongate feature-based mask pattern 300 that causes modulation of the applied light—e.g., the applied light is blocked (or passes through) in varying degrees within the modulating region 304 based on the varying intensity-pass percentage within the modulating region 304.

More particularly, modulating region 304 includes a plurality of elongate features 306 through 314. While a certain number of elongate features are shown in the figures, the number of elongate features in various implementations are not limited to the specific number shown. For example, the number of elongate features (e.g., density of features) in the modulating region 304 may depend on the profiles and structures being formed, as well as the light modulation characteristics or light modulation function used to achieve such profiles and structures.

In the example shown, each of elongate features 306 through 314 includes a continuous feature design having a first feature portion extending in a first direction parallel to a first dimension (e.g., x-dimension) of layout grid 301 (e.g., which may also be referred to as a feature pattern area), a second feature portion extending in a second direction parallel to a second dimension (e.g., y-dimension) of layout grid 301, and a corner feature portion between the first feature portion and the second feature portion. In the example of FIG. 3A, the corner feature portion includes a rounded corner. As will be evident from further descriptions herein, the rounded corner design of each elongate feature enables semiconductor device structures with rounded portions to be fabricated with non-segmented contours.

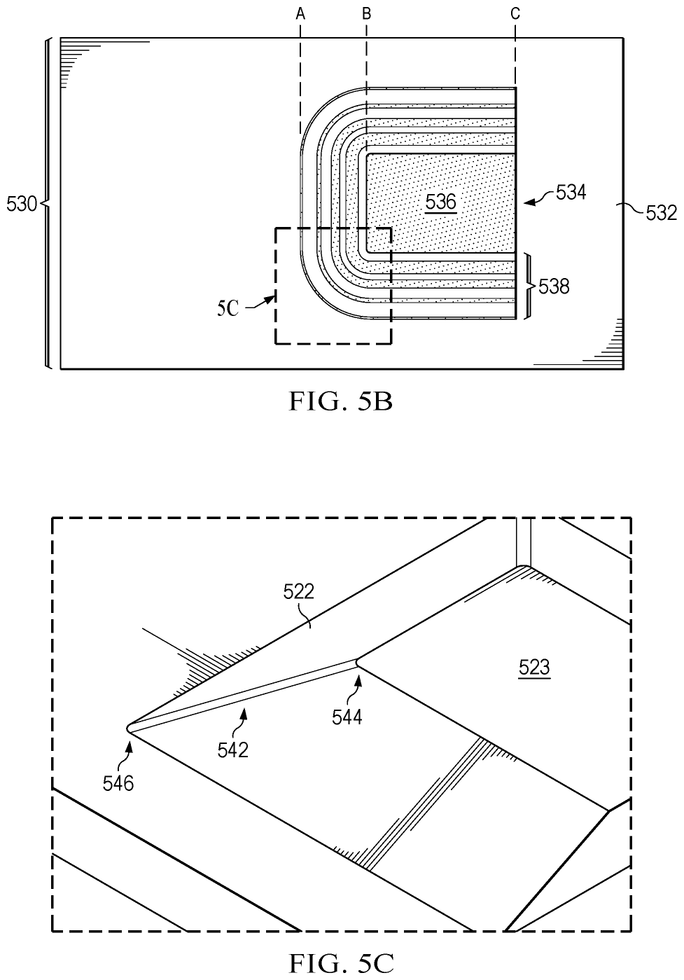

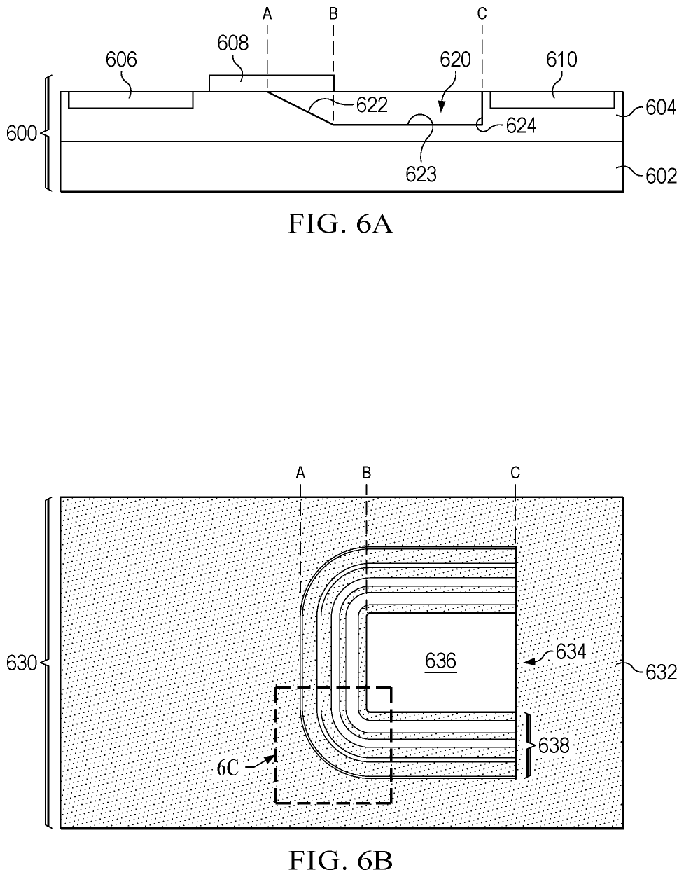

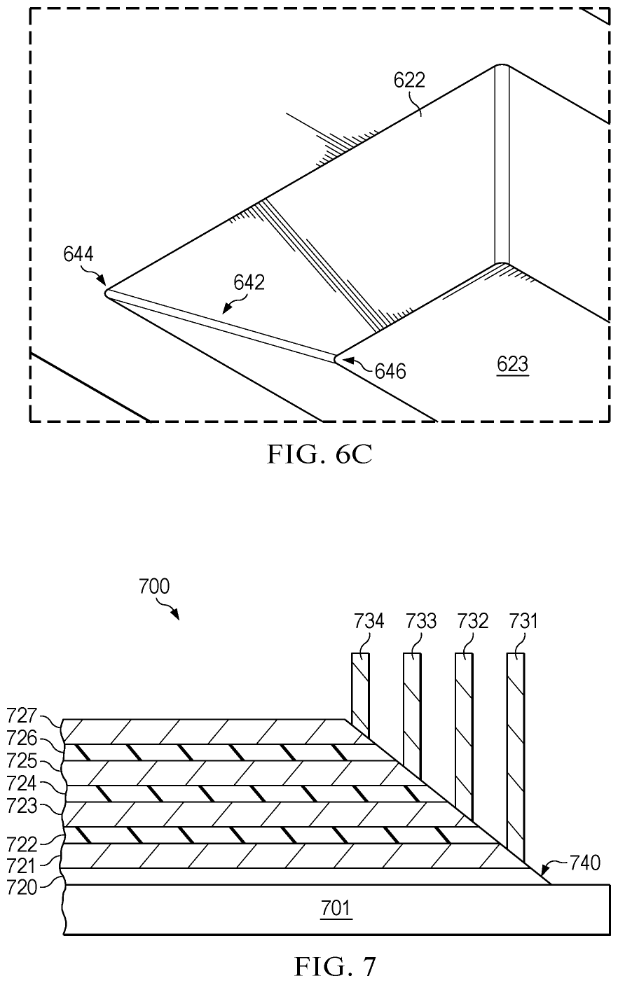

As will be further described in other examples (e.g., FIGS. 5B and 6B), alternative elongate features may be generally u-shaped, e.g., including a third feature portion (not expressly shown in FIG. 3A) parallel to the first feature portion and a second corner portion (not expressly shown in FIG. 3A) between the third feature portion and the second feature portion. However, the present disclosure contemplates mask designs having elongate features arranged in a wide variety of configurations as may be desired/required to fabricate a wide variety of structures in semiconductor and other devices.

Referring back to FIG. 3A, each of elongate features 306 through 314 in modulating region 304 is shown as having a constant width along its length. However, in some alternative examples, one or more of elongate features 306 through 314 can have a varying width along its length. Also, elongate features 306 through 314 in modulating region 304 are illustrated as running parallel to one another. However, in some alternative examples, one or more of elongate features 306 through 314 can be non-parallel over the layout grid 301 with respect to one or more other elongate features 306 through 314.

Still further, elongate features 306 through 314 in modulating region 304 are shown at increasing distances from one another as they are located farther away from non-modulating region 302. In some examples, a constant pitch may be maintained among the elongated features—e.g., the distances between center lines of the elongate features 306 through 314 may be the same. In other examples, a constant pitch may not be maintained among the elongated features—e.g., the distances between center lines of the elongate features 306 through 314 may be different. More particularly, increasingly open areas defined around or between elongate features 306 through 314 are shown as spaces 305 through 313, i.e., space 305 between non-modulating region 302 and elongate feature 306, space 307 between elongate features 306 and 308, space 309 between elongate features 308 and 310, space 311 between elongate features 310 and 312, and space 313 between elongate features 312 and 314. Additional spaces can be defined in modulating region 304, e.g., a space formed beyond elongate feature 314 to the edge of modulating region 304. The rational for this feature design is that the light intensity passing (intensity-pass percentage) through the mask device formed from elongate feature-based mask pattern 300 is dependent upon the spacing between elongate features.

Note that elongate feature-based mask pattern 300 is an example of a mask pattern used to fabricate a clear field mask implementation. As such, non-modulating region 302 and elongate features 306 through 314 correspond to opaque areas on the actual mask device, while spaces 305 through 313 correspond to open areas. In a dark field mask implementation, a reverse correspondence exists, e.g., non-modulating region 302 and elongate features 306 through 314 correspond to open areas on the actual mask device, while spaces 305 through 313 correspond to opaque areas.

As compared to pixel-based mask pattern 200, where the intensity-pass percentage is dependent on the uniform pitch area between pixels, pitch between elongate features does not have to be uniform in the elongate feature-based mask pattern design. Accordingly, with respect to elongate feature-based mask pattern 300, the intensity-pass percentage can be controlled or otherwise managed by setting desired distances between consecutive elongate features—e.g., regardless of maintaining a constant pitch between elongated features or not. For example, as shown in FIG. 3A, spaces 307 through 313 increase as the width of each consecutive elongate feature decreases. In alternative examples, each of elongate features 306 through 314 can be the same width while the distance between consecutive elongate features increases, resulting in a non-uniform pitch.

Also, elongate feature-based mask pattern 300 advantageously addresses minimum spacing between features for a given intensity-pass percentage. Recall that pixel-based mask pattern 200 described above in the context of FIG. 2C has a minimum spacing limitation in both the x and y dimensions. In contrast, since each elongate feature is a singular feature (e.g., effectively replacing a set of multiple pixels), the minimum spacing that limits the pixel-based mask pattern design in the x-dimension is eliminated. Furthermore, since maintaining uniform pitch is not necessary with the elongate feature-based mask pattern design, a minimum spacing in the y-dimension to achieve an equivalent intensity-pass percentage is relaxed as described below.

For example, as illustrated in FIG. 3B, assuming a 10% intensity-pass percentage (e.g., 10% of the applied light passes through the mask device), a pair of elongate features 318 generated on respective elongate cells 319 of a layout grid are designed to achieve an intensity-pass percentage of 10%. Note that, for ease of description, FIG. 3B shows elongate features 318 having the same width. Also, since the elongate features 318 are not dependent on the underlying grid, alternative cell layouts can be used such as is the case with elongate cells 319. Assuming each elongate cell 319 is 100 nm×600 nm in area, each elongate feature 318 can have a fill factor of 90%, e.g., the elongate feature area is 90 nm×600 nm, to achieve the 10% intensity pass. As such, the minimum spacing in the y-dimension between the two elongate features 318 is 20 nm due to a 10 nm border at the top and bottom of each elongate feature 318 dictated by the 90% fill factor. Advantageously, such a relaxation of minimum spacing between features enables use of many commercial pattern writing systems (e.g., laser-based pattern writing system) that would otherwise have a problem with forming features on the mask device with minimum distance limits imposed by the use of a pixel-based mask pattern.

Referring now to FIG. 3C, a schematic cross-sectional view is shown of a mask device 320 (e.g., the mask device 120 described with reference to FIG. 1) including a light-passing substrate 322 with a patterned opaque layer 324 (e.g., the patterned opaque layer 114 described with reference to FIG. 1) formed thereon. Mask device 320 is an example of a mask device that is fabricated based on elongate feature-based mask pattern 300 of FIG. 3A. More particularly, similar to mask device fabrication process 100 described above in the context of FIG. 1, elongate feature-based mask pattern 300 is applied to an opaque layer via a pattern writing system (e.g., pattern applying tool 104, a laser-based pattern writing system) to create patterned opaque layer 324 with elongate features formed therein. FIG. 3D illustrates a 3D view of mask device 320. Note that while mask device 320 is an example of a clear field mask implementation, the present disclosure is not limited thereto and thus is intended to cover dark field mask implementations as well as other mask implementations.

An elongate feature in a mask pattern generated on a CAD system corresponds to an elongate feature formed via the pattern writing system on the mask device. Accordingly, elongate feature-based mask pattern 300 of FIG. 3A is applied to the opaque layer to generate patterned opaque layer 324 on mask device 320 of FIGS. 3C and 3D. More particularly, non-modulating region 302 in elongate feature-based mask pattern 300 corresponds to non-modulating region 332 in mask device 320, modulating region 304 in elongate feature-based mask pattern 300 corresponds to modulating region 334 in mask device 320, elongate features 306 through 314 in elongate feature-based mask pattern 300 correspond to elongate features 336 through 344 in mask device 320, and spaces 305 through 313 in elongate feature-based mask pattern 300 correspond to open areas 335 through 343 which expose a surface 345 of light-passing substrate 322 in mask device 320.

Further, by way of example, the resolution of the elongate features in mask device 320 can be designed to be below the resolution limit of the photolithography processes, tools and systems used to form the profiles and structures in the semiconductor devices being fabricated.

Accordingly, to enable light applied to mask device 320 to cause modulation of the thickness of the photoresist layer applied to the semiconductor device being fabricated as desired, elongate features 336 through 344 are disposed at increasing distances from one another with correspondingly increasing open areas 335 through 343 of surface 345 of light-passing substrate 322 therebetween.

While a certain number of elongate features are shown in the figures, the number of elongate features in various implementations are not limited to the specific number shown. For example, the number of elongate features (e.g., density of features) in the modulating region 334 may depend on the profiles and structures being formed, as well as the light modulation characteristics or light modulation function used to achieve such profiles and structures.

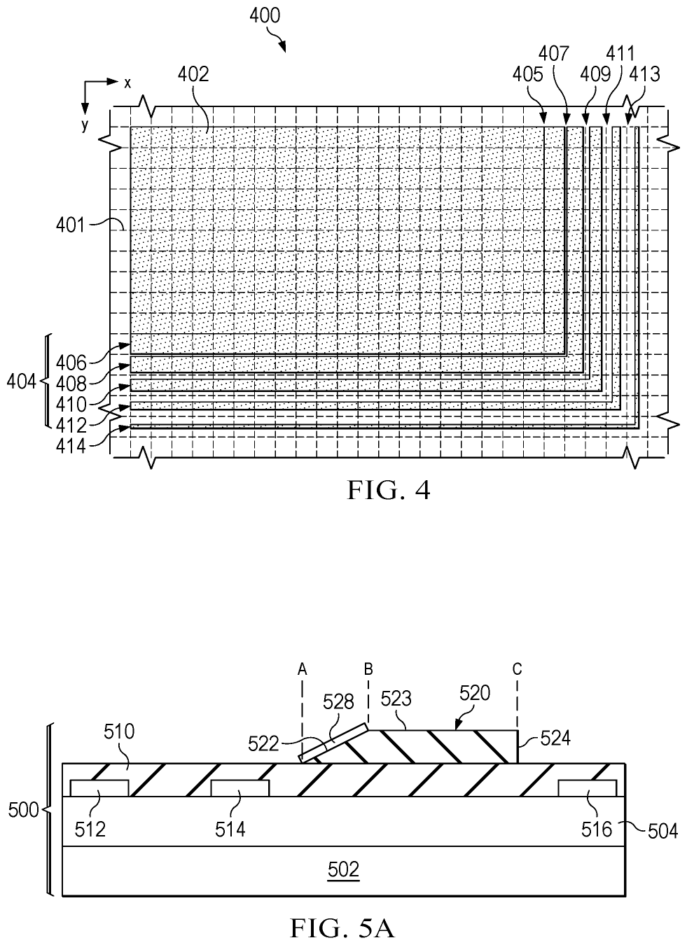

Alternative examples of elongate feature-based mask patterns and mask devices fabricated therefrom are contemplated by the present disclosure. By way of further example, FIG. 4 illustrates an alternative elongate feature-based mask pattern design in the form of an elongate feature-based mask pattern 400. While shown on a coordinate grid of equally-sized square cells referenced as a layout grid 401, similar to elongate feature-based mask pattern 300, elongate feature-based mask pattern 400 is not constrained by such a layout grid or a uniform pitch. Elongate feature-based mask pattern 400 is another example of a mask pattern designed for a clear field mask implementation, e.g., elongate features correspond to opaque areas. However, a dark field mask implementation of elongate feature-based mask pattern 400 is contemplated where elongate features of the mask pattern correspond to open areas.

As shown, elongate feature-based mask pattern 400 includes a non-modulating region 402 and a modulating region 404. Modulating region 404 includes a plurality of elongate features 406 through 414. In the example shown, each of elongate features 406 through 414 includes a continuous feature design having a first feature portion extending in a first direction parallel to a first dimension (e.g., x-dimension) of layout grid 401 (e.g., a feature pattern area), a second feature portion extending in a second direction parallel to a second dimension (e.g., y-dimension) of layout grid 401, and a corner feature portion between the first feature portion and the second feature portion. However, while elongate feature-based mask pattern 300 in FIG. 3A has a rounded corner shape for the corner feature portion, elongate feature-based mask pattern 400 in FIG. 4 includes a squared corner design. Also, similar to elongate feature-based mask pattern 300, elongate feature-based mask pattern 400 can be extended where each elongate feature is generally u-shaped.

Still further, elongate features 406 through 414 in modulating region 404 are shown at increasing distances from one another as they are located farther away from non-modulating region 402. As with the elongate features 306 through 314 in modulating region 304 described with reference to FIG. 3A, in some examples, a constant pitch may be maintained among the elongated features—e.g., the distances between center lines of the elongate features 406 through 414 may be the same. In other examples, a constant pitch may not be maintained among the elongated features—e.g., the distances between center lines of the elongate features 406 through 414 may be different. More particularly, increasingly open areas are shown as spaces 405 through 413, e.g., space 405 between non-modulating region 402 and elongate feature 406, space 407 between elongate features 406 and 408, space 409 between elongate features 408 and 410, space 411 between elongate features 410 and 412, and space 413 between elongate features 412 and 414. Additional spaces can be defined in modulating region 404, e.g., a space formed beyond elongate feature 414 to the edge of modulating region 404. As described above, the increasing of distances between consecutive elongate features enables the modulation of light intensity or dosage in accordance with the modulation function of the grayscale photolithography process being implemented.

Elongate feature-based mask pattern 400 results in a clear field mask device (not expressly shown) similar to mask device 320 in FIGS. 3C and 3D which functions in a similar way to cause modulation of a photoresist layer thickness. A main difference, however, in a mask device resulting from elongate feature-based mask pattern 400 as compared with mask device 320 is that the elongate features have a squared corner instead of a rounded corner.

The squared corner design of each of elongate features 406 through 414 provides additional advantages in relation to the underlying structures that are sought to be formed. For example, where 3D sloped structures without rounded corners or curves are desired in a semiconductor or other device, elongate feature-based mask pattern 400 can be utilized to fabricate a mask device capable of forming such structures. Also, in less complex grayscale structure fabrications, adjustment of spacings of features to accommodate various light intensity modulation functions can be difficult in the pixel-based mask pattern approach, e.g., a need to rearrange many pixels and pixels sets in the design. Advantageously, however, elongate feature-based mask pattern 400 enables case of adjustment of distances between singular elongate features. Accordingly, elongate feature-based mask pattern 400 can easily accommodate any spacings desired to implement any particular light intensity modulation function that may be used to form an underlying structure. In contrast, adjustment of pixels in a pixel-based mask pattern to accommodate a different light intensity modulation function requires a significant redesign effort on the CAD system.

Given the above-described illustrative elongate feature-based mask patterns and devices, there are many examples of semiconductor and other device fabrications that can benefit therefrom. For example, semiconductor and other structures formed with a mask device fabricated from an elongate feature-based mask pattern advantageously do not exhibit a segmentation issue, e.g., steps, angles, edges, waviness, and/or undulation, in rounded portions of the structure. As described above, the formation of unwanted segmented contours (e.g., in rounded portions of the structure) is one technical drawback exhibited by the use of a pixel-based mask design to attempt to form structures with rounded portions. Several examples of semiconductor devices having structures formed therein using an elongate feature-based mask pattern will now be described.

In general, structures with rounded portions (e.g., sloped sidewalls with rounded corners or curves) can be particularly useful in high voltage (HV) semiconductor devices—e.g., to mitigate certain undesired results associated with abrupt changes in voltage and or electric field distribution. Examples of HV semiconductor devices include gallium nitride (GaN) devices and laterally-diffused metal oxide semiconductor (LDMOS) devices used in microwave and radio frequency amplifier applications. These field effect transistor (FET) devices are typically designed to operate in high voltage applications, e.g., power amplifiers that operate with voltage levels on the order of tens or hundreds of volts. The ability to generate structures with rounded portions with non-segmented contours, in accordance with elongate feature-based mask designs, has operational benefits in such HV semiconductor devices.

Referring now to FIG. 5A, a high-level cross-sectional view of a GaN device 500 formed in accordance with an example of the present disclosure is shown. Note that layers, regions and other device elements in FIG. 5A are shown in a general relation to one another (e.g., in, on, above, below, proximate to, or the like) to denote a high-level configuration of a GaN device 500 with a structure formed via an elongate feature-based mask device. Thus, fabrication details of a GaN device, including additional layers, regions, and other device elements, are omitted so as not to obscure the disclosure.

More particularly, as shown, GaN device 500 includes a substrate 502 having GaN layers 504 formed thereon. GaN layers 504 may include (not expressly shown) a GaN layer and a GaN-based alloy layer (e.g., AlGaN layer) having a heterojunction formed therebetween. A heterojunction is an interface between two layers or regions of dissimilar semiconductors, e.g., semiconductor materials having unequal band gaps. In the case of a GaN device, forming a heterojunction between the GaN layer and the GaN-based alloy layer induces a 2-dimensional electron gas (2DEG) layer in the GaN layer proximate the interface between the GaN layer and the GaN-based alloy layer. The 2DEG layer provides a channel for current conduction between a source and a drain of the GaN device.

As further shown in FIG. 5A, a first dielectric layer 510 (e.g., silicon nitride or SiN) is formed on GaN layers 504 with a source 512, a gate 514, and a drain 516 formed in relation to first dielectric layer 510. A second dielectric layer 520 (e.g., SiN) is formed on first dielectric layer 510. Second dielectric layer 520 is patterned with grayscale lithography using an elongate feature-based mask device according to an example of the present disclosure, e.g., an elongate feature-based mask device of FIG. 5B. While not expressly shown in FIG. 5A, a positive photoresist layer is used to first create a profile using the elongate feature-based mask device which is substantially the same or similar to the profile of the resulting shape of the second dielectric layer 520 depicted in FIG. 5A. Thereafter, the profile of the photoresist layer is then transferred to second dielectric layer 520, via one or more process steps including etching, to pattern second dielectric layer 520 as shown.

More particularly, second dielectric layer 520 is patterned to form a sloped sidewall 522 that extends down from a top surface 523 on three sides of second dielectric layer 520 (only one side is visible in the cross-section of FIG. 5A). A vertical sidewall 524 is formed on the remaining side of second dielectric layer 520 as shown. Sloped sidewall 522 is formed in order to accommodate a similarly-sloped field plate 528 formed on sloped sidewall 522 and positioned between gate 514 and drain 516. A field plate is a conductive element utilized in GaN and other semiconductor devices to shape or modulate the electric field locally present in the conductive channel (e.g., in the GaN layers). Properly shaping the electric field has been shown to improve one or more operational parameters of the device. A field plate can be coupled to the gate or the source of the GaN device in some examples.

Referring now to FIG. 5B, a top view of an elongate feature-based mask device 530 used to pattern second dielectric layer 520 of GaN device 500 is shown. In this example, elongate feature-based mask device 530 is a clear field mask implementation which includes a light-passing substrate 532 and a patterned opaque layer 534. Patterned opaque layer 534 includes opaque areas (for blocking light) formed on a surface of light-passing substrate 532 with open areas (for passing light) between or otherwise around the opaque features.

As is evident, patterned opaque layer 534 is based on the above-described elongate feature-based mask pattern 300 (FIG. 3A) but varies in that the pattern formed in FIG. 5B is composed of mirror images of elongate feature-based mask pattern 300 combined to form a generally u-shaped pattern. Accordingly, in order to form the resulting shape of second dielectric layer 520, patterned opaque layer 534 includes a non-modulating region 536 and a modulating region 538 positioned around non-modulating region 536 including a plurality of u-shaped elongate features having rounded corners. Further, the u-shaped elongate features are positioned at increasing distances from one another as they are located farther away from non-modulating region 536. This results in open spaces with increasing distances between non-modulating region 536 and each of the u-shaped elongate features in modulating region 538. As described above, the increasing distances between the elongate features enables light, applied during the grayscale lithography process, to be modulated locally on the positive photoresist layer (not shown in FIG. 5A) to form the initial profile for the resulting shape of second dielectric layer 520.

Lines A, B, C, shown in both FIGS. 5A and 5B, illustrate correspondence between patterned opaque layer 534 and the resulting shape of second dielectric layer 520. For example, top surface 523 and vertical sidewall 524 of second dielectric layer 520, defined between lines B and C, are formed based on the opaque shape of non-modulating region 536 of FIG. 5B. Sloped sidewall 522 of FIG. 5A, at least partially defined between lines A and B, is formed by the opaque elongate features of modulating region 538.

FIG. 5C is a three-dimensional view of a section of second dielectric layer 520 that is formed by the part of elongate feature-based mask device 530 highlighted by the box drawn in FIG. 5B. As shown in FIG. 5C, sloped sidewall 522 includes a sloped corner 542 having a top rounded portion 544 where sloped corner 542 meets with top surface 523 of second dielectric layer 520, and a bottom rounded portion 546 where sloped corner 542 meets with a top surface of first dielectric layer 510. Due to the u-shaped configuration of the elongate features of elongate feature-based mask device 530, a similar sloped corner (not shown in FIG. 5C) is formed on the opposing side of sloped sidewall 522. Field plate 528 is formed on sloped sidewall 522 following the contours of sloped sidewall 522 with similar rounded portions.

Advantageously, using elongate feature-based mask device 530, the rounded portions of sloped sidewall 522 are formed without exhibiting the above-described segmentation issue, e.g., steps, angles, edges, waviness, and/or undulation. Thus, since field plate 528 follows the contours of sloped sidewall 522, field plate 528 also has rounded portions that do not exhibit the segmentation issue. As described above, the ability to generate structures with rounded portions with non-segmented contours has operational benefits in HV semiconductor devices such as, e.g., GaN device 500.

By way of example, assuming a sloped sidewall 522 of approximately thirty degrees is required or otherwise desired, the following table, Table 1, illustrates examples of critical dimensions and open areas given a mask device with a specific number of elongate features in the modulating region. While FIG. 5B depicts only four elongate features for the sake of ease of illustration, mask devices formed according to the present disclosure can have a larger or smaller number of elongate features. In the tabular example below, it is assumed that the mask device includes twenty elongate features (e.g., corresponding to i=0 through 19). The open area (OA) and critical dimension (CD) values in Table 1 are in micrometers (μm).

TABLE 1

| i | OA | CD |
|---|---|---|
| 0 | 0.923 | 0.023 |
| 1 | 0.88 | 0.036 |
| 2 | 0.837 | 0.049 |
| 3 | 0.793 | 0.062 |
| 4 | 0.75 | 0.075 |
| 5 | 0.707 | 0.088 |
| 6 | 0.663 | 0.101 |
| 7 | 0.62 | 0.114 |
| 8 | 0.577 | 0.127 |
| 9 | 0.533 | 0.140 |
| 10 | 0.49 | 0.153 |
| 11 | 0.447 | 0.166 |
| 12 | 0.403 | 0.179 |
| 13 | 0.36 | 0.192 |
| 14 | 0.317 | 0.205 |
| 15 | 0.273 | 0.218 |
| 16 | 0.23 | 0.231 |
| 17 | 0.187 | 0.244 |
| 18 | 0.143 | 0.257 |
| 19 | 0.1 | 0.270 |

In terms of positioning of each elongate feature in the context of a clear field mask device configuration similar to FIG. 5B, the elongate feature corresponding to i=19 in Table 1 would be closest to non-modulating region 536 and the widest u-shaped elongate feature in modulating region 538, while the elongate feature corresponding to i=0 in Table 1 would be farthest from non-modulating region 536 and the narrowest u-shaped elongate feature in modulating region 538. OA in the second column corresponds to the open area width between consecutive elongate features. Thus, as the width of each consecutive elongate feature decreases, the open area width between consecutive elongate features increases. In the last column, CD refers to the greyscale width on a wafer level (e.g., in second dielectric layer 520). Assuming a 5:1 scaled correspondence between the mask device and the wafer, the corresponding width on the mask level (e.g., width of an elongate feature in modulating region 538) would be five times the width shown in the CD column above, e.g., the elongate feature corresponding to i=0 would have a width of 0.115 μm. In this example of Table 1, it is assumed that pitch remains constant and is 0.300 μm for all elongate features.

FIG. 6A is a high-level cross-sectional view of an LDMOS device 600 formed in accordance with an example of the present disclosure. Note that layers, regions and other device elements in FIG. 6A are shown in a general relation to one another (e.g., in, on, above, below, proximate to, or the like) to denote a high-level configuration of a LDMOS device 600 with a structure formed via an elongate feature-based mask device. Thus, fabrication details of a LDMOS device, including additional layers, regions, and other device elements, are omitted so as not to obscure the disclosure.

More particularly, as shown, LDMOS device 600 includes a substrate 602 having a silicon (Si) layer 604 formed thereon. Si layer 604 is formed with a source 606, a gate 608, and a drain 610 disposed as shown in relation to Si layer 604. Si layer 604 also includes a trench isolation region 620 formed therein. In LDMOS devices, the drain and source have a relatively large spacing between them and the device has lateral diffusions that are used to produce a well-controlled conductive channel under the gate. A trench isolation region can be formed in a layer of the LDMOS device to advantageously affect operational parameters of the device.

Trench isolation region 620 is patterned with grayscale lithography using an elongate feature-based mask device according to an example of the present disclosure, e.g., an elongate feature-based mask device of FIG. 6B. While not expressly shown in FIG. 6A, a positive photoresist layer is used to first create a profile using the elongate feature-based mask device which is substantially the same or similar to the profile of the resulting shape of the trench isolation region 620 depicted in FIG. 6A. Thereafter, the profile of the photoresist layer is then transferred to Si layer 604, via one or more process steps including etching, to pattern trench isolation region 620 as shown.

More particularly, trench isolation region 620 is patterned to form a sloped sidewall 622 that extends up from a bottom surface 623 on three sides of trench isolation region 620. A vertical sidewall 624 is formed on the remaining side of trench isolation region 620 as shown. Sloped sidewall 622 is formed in order to provide gradually increasing spacing between the gate 608 and the surface of the Si layer 604. In this manner, the portion of the gate 608 above the sloped sidewall 622 may function as a field plate. In other words, gate 608 is formed with poly-Si including a portion over the trench isolation region 620. Such a portion of the gate 608 over sloped sidewall 622 may function as a conductive field plate.

Referring now to FIG. 6B, a top view of an elongate feature-based mask device 630 used to pattern trench isolation region 620 of LDMOS device 600 is shown. In this example, elongate feature-based mask device 630 is a dark field mask implementation which includes a light-passing substrate 632 and a patterned opaque layer 634. As such, patterned opaque layer 634 includes opaque areas (for blocking light) formed on a surface of light-passing substrate 632 with open areas (for passing light) forming the mask features.

As is evident, patterned opaque layer 634 is based on the above-described elongate feature-based mask pattern 300 (FIG. 3A) but varies in that mirror images of a dark field version of elongate feature-based mask pattern 300 are combined to form patterned opaque layer 634. Accordingly, in order to form trench isolation region 620, patterned opaque layer 634 includes a non-modulating region 636 (e.g., the applied light passes through the non-modulating region 636 in its entirety) and a modulating region 638 positioned around non-modulating region 636 including a plurality of u-shaped elongate features having rounded corners. Further, the u-shaped elongate features are positioned at increasing distances from one another as they are located farther away from non-modulating region 636. This results in opaque spaces between and around open areas formed by non-modulating region 636 and each of the u-shaped elongate features in modulating region 638. As described above, the increasing distances between the elongate features enables light, applied during the grayscale lithography process, to be modulated locally on the positive photoresist layer (not shown in FIG. 6A) to form the initial profile in the photoresist layer for forming the resulting shape of trench isolation region 620.

In addition, lines A, B, and C are shown across FIGS. 6A and 6B. The lines illustrate correspondence between patterned opaque layer 634 and the resulting shape of trench isolation region 620. Bottom surface 623 and vertical sidewall 624 of trench isolation region 620, defined between lines B and C, are formed based on the open shape of non-modulating region 636 of FIG. 6B. Sloped sidewall 622 of FIG. 6A, at least partially defined between lines A and B, is formed by the open elongate features of modulating region 638.

FIG. 6C is a three-dimensional view of a section of trench isolation region 620 that is formed by the part of elongate feature-based mask device 630 highlighted by the box drawn in FIG. 6B. As shown in FIG. 6C, sloped sidewall 622 includes a sloped corner 642 having a top rounded portion 644 where sloped corner 642 meets with a top surface of Si layer 604, and a bottom rounded portion 646 where sloped corner 642 meets with bottom surface 623. Due to the u-shaped configuration of the elongate features of elongate feature-based mask device 630, a similar sloped corner (not shown in FIG. 6C) is formed on the opposing side of sloped sidewall 622.

Advantageously, using elongate feature-based mask device 630, the rounded portions of sloped sidewall 622 are formed without exhibiting the above-described segmentation issue, i.e., steps, angles, edges, waviness, and/or undulation. Thus, the electric field distribution during operation of LDMOS device 600 resulting from the rounded portions of the sloped sidewall 622 is expected to be less prone to exhibit undesirable effects associated with the segmentation issue. As described above, the ability to generate structures with rounded portions with non-segmented contours has operational benefits in HV semiconductor devices such as, e.g., LDMOS device 600.

By way of yet another example of a device that is formed using an elongate feature-based mask design, FIG. 7 shows a high-level cross-sectional view of a stacked capacitor device 700 (e.g., a device with a capacitor stack) formed in accordance with an example of the present disclosure. Note that layers, regions and other device elements in FIG. 7 are shown in a general relation to one another (e.g., in, on, above, below, proximate to, or the like) to denote a high-level configuration of a stacked capacitor device 700 with a structure formed via an elongate feature-based mask device. Thus, fabrication details of a stacked capacitor device, including additional layers, regions, and other device elements, are omitted so as not to obscure the disclosure.

As shown, stacked capacitor device 700 includes a substrate 701 on which one or more base layers 720 are formed. Base layers 720 can comprise one or more base conductive plates and/or one or more base dielectric layers. A set of alternating metal layers 721, 723, 725 and 727 and dielectric layers 722, 724 and 726 are formed on base layers 720. In some examples, each set of two metal layers with a dielectric layer in between can function as a capacitor within the semiconductor device in which the stacked capacitor device 700 is formed. To electrically connect with each of the conductive metal layers 721, 723, 725 and 727, a set of contacts 731, 732, 733 and 734 are respectively formed along a sloped sidewall 740. As shown, sloped sidewall 740 is patterned through alternating metal layers 721, 723, 725 and 727 and dielectric layers 722, 724 and 726.

While not expressly shown in FIG. 7, a clear field mask device such as elongate feature-based mask device 530 (FIG. 5B) or a dark field mask device such as elongate feature-based mask device 630 (FIG. 6B) can be used with a positive photoresist to form sloped sidewall 740. Also, while FIG. 7 shows sloped sidewall 740 patterned through each of alternating metal layers 721, 723, 725, 727 and dielectric layers 722, 724, 726, in alternative examples, sloped sidewall 740 can be patterned through less of the layers as may be desired/required for the semiconductor device design.

Semiconductor devices generally illustrated in FIGS. 5A through 7 are merely intended as examples of devices which benefit from the use of elongate feature-based mask designs of the present disclosure. Similarly, the profiles and structures shown in the figures are also merely intended as examples of profiles and structures that can be formed via such elongate feature-based mask designs. Accordingly, the present disclosure contemplates a wide variety of other profiles, structures and devices that can be formed using such elongate feature-based mask designs.

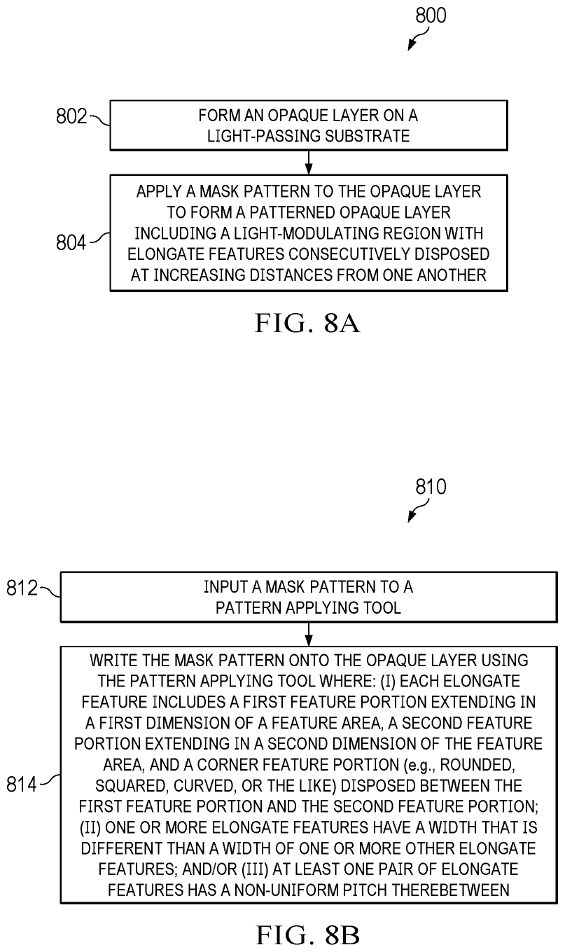

Referring now to FIGS. 8A and 8B, methodologies for fabricating mask devices according to examples of the present disclosure are shown. Mask device fabrication methodologies shown in FIGS. 8A and 8B are intended to fabricate elongate feature-based mask devices based on any of the elongate feature-based mask patterns illustratively described herein, as well as variations thereof.

More particularly, FIG. 8A shows a method 800 for fabricating a mask device. In method 800, step 802 forms an opaque layer on a light-passing substrate. Step 804 then applies a mask pattern to the opaque layer to form a patterned opaque layer including a light-modulating region with elongate features consecutively disposed at increasing distances from one another.

FIG. 8B shows a method 810 for applying the mask pattern to the opaque layer (e.g., an example of step 804 in method 800). Step 812 inputs the mask pattern to a pattern applying tool. Step 814 then writes the mask pattern onto the opaque layer using the pattern applying tool. In some examples, the mask pattern can be written onto the opaque layer using the pattern applying tool such that: (i) each elongate feature includes a first feature portion extending in a first dimension of a feature area, a second feature portion extending in a second dimension of the feature area, and a corner feature portion (e.g., rounded, squared, curved, or the like) disposed between the first feature portion and the second feature portion; (ii) one or more elongate features have a width that is different than a width of one or more of the other elongate features; and/or (iii) at least one pair of elongate features has a non-uniform pitch therebetween.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A mask device, comprising:
a light-passing substrate; and
a patterned opaque layer disposed on the light-passing substrate, wherein the patterned opaque layer comprises a light-modulating region with elongate features consecutively disposed at increasing distances from one another.

2. The mask device of claim 1, wherein each of the elongate features corresponds to an opaque area of the patterned opaque layer.

3. The mask device of claim 1, wherein each of the elongate features corresponds to an open area of the patterned opaque layer.

4. The mask device of claim 1, wherein each of the elongate features further comprises:
a first feature portion extending in a first dimension of a feature area;
a second feature portion extending in a second dimension of the feature area; and
a corner feature portion disposed between the first feature portion and the second feature portion.

5. The mask device of claim 4, wherein the corner feature portion comprises a rounded corner.

6. The mask device of claim 4, wherein the corner feature portion comprises a squared corner.

7. The mask device of claim 4, wherein each of the elongate features further comprises:
a third feature portion extending parallel to the first feature portion; and
another corner feature portion disposed between the third feature portion and the second feature portion.

8. The mask device of claim 1, wherein one or more of the elongate features have a width that is different than a width of one or more of the other elongate features.

9. The mask device of claim 1, wherein at least one pair of the elongate features has a non-uniform pitch therebetween.

10. The mask device of claim 1, wherein:
the light-passing substrate comprises a material including at least one of quartz, fused silica, and glass; and
opaque areas of the patterned opaque layer comprise a material including at least one of chrome, chromium, and metal oxide.

11. A method of fabricating a mask device, comprising:
forming an opaque layer on a light-passing substrate; and
applying a mask pattern to the opaque layer to form a patterned opaque layer comprising a light-modulating region with elongate features consecutively disposed at increasing distances from one another.

12. The method of claim 11, wherein each of the elongate features corresponds to an opaque area of the patterned opaque layer.

13. The method of claim 11, wherein each of the elongate features corresponds to an open area of the patterned opaque layer.

14. The method of claim 11, wherein applying the mask pattern to the opaque layer further comprises inputting the mask pattern to a pattern applying tool.

15. The method of claim 14, wherein applying the mask pattern to the opaque layer further comprises writing the mask pattern onto the opaque layer using the pattern applying tool.

16. The method of claim 11, wherein each of the elongate features is formed to further comprise:
a first feature portion extending in a first dimension of a feature area;
a second feature portion extending in a second dimension of the feature area; and
a corner feature portion disposed between the first feature portion and the second feature portion.

17. A semiconductor device, comprising:
a substrate; and
at least one layer disposed in relation to the substrate, wherein the at least one layer comprises a structure with at least one rounded portion having a non-segmented contour.

18. The semiconductor device of claim 17, further comprising:
a source, a drain, and a gate disposed in relation to the layer;
wherein the structure with at least one rounded portion having a non-segmented contour comprises a sloped sidewall of a dielectric region configured for a field plate disposed between the source and the drain.

19. The semiconductor device of claim 17, wherein the structure with at least one rounded portion having a non-segmented contour comprises a sloped sidewall configured for one or more contacts associated with one or more layers of a capacitor stack.

20. The semiconductor device of claim 17, further comprising:
a source, a drain, a gate disposed in relation to the layer;
wherein the structure with at least one rounded portion having a non-segmented contour comprises a sloped sidewall of an isolation region configured to enable at least a portion of the gate disposed there above to function as a field plate.
